(19) United States
(12) Patent Application Publication
(10) Pub. No.: US 2025/0266520 A1
(43) Pub. Date: Aug. 21, 2025

(54) BATTERY MANAGEMENT DEVICE

(71) Applicant: TOYOTA JIDOSHA KABUSHIKI KAISHA, Toyota-shi (JP)

(72) Inventor: Yuki IMADE, Okazaki-shi (JP)

(73) Assignee: TOYOTA JIDOSHA KABUSHIKI KAISHA, Toyota-shi (JP)

(21) Appl. No.: 18/962,294

(22) Filed: Nov. 27, 2024

(30) Foreign Application Priority Data
Feb. 20, 2024 (JP) 2024-023849

(51) Int. Cl. H01M 10/48; H01M 10/42

(52) U.S. Cl. CPC H01M 10/488; H01M 10/425; H01M 2010/4271; H01M 2220/20

(57) ABSTRACT

The battery management device includes: a calculation unit that calculates SOC and the coefficient from the measured values of the current and the voltage of the battery based on an SOC of the battery and an estimation model that estimates the polarization voltage according to a coefficient relating to an increase in a voltage corresponding to SOC among the polarization voltages caused by discharging of the battery; and a notification unit that, when SOC is equal to or less than a threshold value, notifies the user of charge of the battery, and the notification unit decreases the threshold value as the coefficient decreases.

### CROSS-REFERENCE TO RELATED APPLICATION

This application claims priority to Japanese Patent Application No. 2024-023849 filed on Feb. 20, 2024, incorporated herein by reference in its entirety.

### BACKGROUND

### 1. Technical Field

The disclosure relates to a battery management device.

### 2. Description of Related Art

Japanese Unexamined Patent Application Publication No. 2018-77199 (JP 2018-77199 A), for example, discloses technology for estimating a charge rate (State Of Charge (SOC)) of a battery using an equivalent-circuit model of a battery for a vehicle, and managing the battery. The SOC serves as an indication for prompting a user to charge the battery.

### SUMMARY

For example, in a lithium-ion battery, diffusion resistance due to polarization increases in a region in which the SOC is low (e.g., 20% or lower) during discharging. When the diffusion resistance increases, available power of the battery is decreases, and accordingly, even when the user is prompted to charge the battery in accordance with a decrease in the SOC, there conceivably may be cases in which there actually is an excessive surplus in the power of the battery, or conversely, cases in which the power is excessively insufficient and operations of loads are adversely affected.

Accordingly, the disclosure provides a battery management device that can appropriately prompt a user to charge a battery.

A battery management device according to the disclosure includes a calculation unit that, based on an estimation model that estimates a polarization voltage in accordance with a state of charge (SOC) of a battery and a coefficient relating to increase in voltage corresponding to the SOC out of polarization voltage due to discharging of the battery, calculates the SOC and the coefficient from measured values of current and voltage of the battery, and

a notification unit that, when the SOC is no greater than a threshold value, gives a notification to prompt a user to charge the battery, in which
the smaller the coefficient is, the lower the notification unit sets the threshold value.

In the above battery management device, the notification unit may change the threshold value such that a linear relationship is established with the coefficient.

In the above battery management device, the calculation unit may periodically calculate the voltage of the battery using the estimation model, and calculate the SOC and the coefficient such that a difference between a calculated value of the voltage of the battery and the measured value of the voltage of the battery converges.

In the above battery management device, the battery may be a lithium-ion battery.

In the battery management device, the battery may supply electric power to an electric motor that drives a vehicle.

According to the disclosure, the user can be appropriately prompted to charge the battery.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a configuration diagram schematically illustrating an example of a battery system of a vehicle V;

FIG. 2 is a diagram illustrating an exemplary change in the diffusion-resistance of a lithium-ion battery during charging and discharging of SOC;

FIG. 3A is a functional block diagram illustrating an example of a state calculation unit;

FIG. 3B is a diagram illustrating an example of a temporal change in SOC during discharging of a battery cell;

FIG. 4 is a diagram illustrating an exemplary change in the discharge-polarization voltage with respect to SOC;

FIG. 5 is a diagram illustrating an exemplary threshold map; and

FIG. 6 is a flowchart illustrating an example of an operation of the control device.

### DETAILED DESCRIPTION OF EMBODIMENTS

### Battery System Configuration

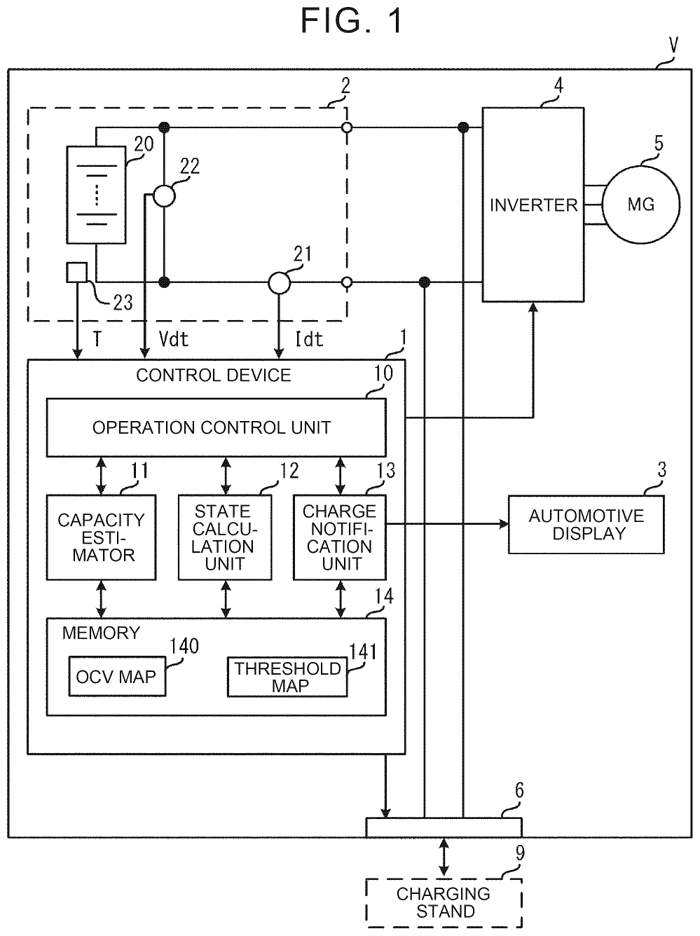

FIG. 1 is a configuration diagram schematically illustrating an example of a battery system of a vehicle V. The vehicle V comprises a control device 1 comprising one or more ECU (Electronic Control Unit) and a battery pack 2, which is a power supply. The vehicle V includes an in-vehicle display 3 that displays various types of information notified to the occupant (user), an inlet 6 for charging and discharging the battery pack 2, an inverter 4 that converts a direct current into an alternating current, and an electric motor (MG) 5 that is a power source of the vehicle V.

The battery pack 2 includes a battery cell 20 that is an example of a battery, a current sensor 21 that detects a current flowing in the battery cell 20, a voltage sensor 22 that detects a voltage of the battery cell 20, and a temperature sensor 23 that detects a temperature T of the battery cell 20. The detected values of the current sensor 21, the voltage sensor 22, and the temperature sensor 23 are output to the control device 1. Examples of the battery cell 20 include, but are not limited to, a lithium ion battery.

The control device 1 is an example of a battery management device. The control device 1 is a computer including CPU (Central Processing Unit), ROM (Read Only Memory), and RAM (Random Access Memory). ECU 1 operates CPU according to the program stored in ROM.

The control device 1 controls the inverter 4. The inverter 4 is connected between the battery pack 2 and the electric motor 5. The inverter 4 converts a direct current into an alternating current by switching operation of a plurality of switching elements such as MOS-FET (Metal-Oxide-Semiconductor Field Effect Transistor). The control device 1 PWM (Pulse Width Modulation) the duty cycle according to the driving condition of the vehicle V to the inverter 4.

Further, the control device 1 controls charging of the battery cell 20. The battery cell 20 has, for example, a configuration in which a plurality of lithium ion batteries are connected in series. The battery cell 20 supplies DC power to the inverter 4. Thus, the electric motor 5 is driven. The battery cell 20 is charged from an external charging station 9 via an inlet 6. The control device 1 instructs, for example, a target value of a current output to the charging station 9 at the time of charging.

The control device 1 includes an operation control unit 10, a capacity estimation unit 11, a state calculation unit 12, and a charge notification unit 13 as software functions formed by a program operation. Note that the operation control unit 10, the capacity estimation unit 11, the state calculation unit 12, and the charge notification unit 13 may be implemented by hardware such as an integrated circuit.

In addition, the control device 1 includes a nonvolatile memory 14 such as an EEPROM (Electrically Erasable Programmable ROM). The memory 14 holds OCV (Open Circuit Voltage) map data (OCV map) 140 and threshold map data (threshold map) 141.

OCV map 140 and the threshold map 141 are generated based on experimental results and simulated results of the properties of the battery cells 20, and are written in advance in the memory 14. OCV map 140 shows correlations between OCV and SOC of the battery cells 20. The threshold map 141 indicates correlations between the threshold value of SOC for promoting the charge of the battery cell 20 and the discharging polarization coefficient to be described later.

The operation control unit 10 instructs the capacity estimation unit 11, the state calculation unit 12, and the charge notification unit 13 to perform an operation in a predetermined sequence. Further, the operation control unit 10 performs control at the time of charging and discharging for the charging station 9 and the inverter 4.

$$Cap = 100 \div ( SOCe - SOCs ) \times Is \qquad ( 1 )$$

The capacity estimation unit 11 estimates the full charge capacity Cap of the battery cell 20 when charging is performed by the charging station 9, for example. For example, the capacity estimation unit 11 calculates the full charge capacity Cap according to Equation (1) above. In Equation (1), Is is an integrated value obtained by integrating the current value of the battery cell 20 for a predetermined period. In Equation (1), SOCs is SOC of the battery cell 20 when the integration of the current of the battery cell 20 is started, and SOCe is SOC of the battery cell 20 when the integration of the current is ended. For example, the capacity estimation unit 11 calculates the integrated value Is from the detected value of the current sensor, and acquires, from OCV map 140, the detected value of the voltage sensor 22 at the time of charging, that is, SOCe and SOCs corresponding to OCV.

The state calculation unit 12 is an example of a calculation unit. The state calculation unit 12 calculates SOC and the discharge polarization coefficient from the measured values of the current and the voltage of the battery cell 20 based on the estimation model that estimates the discharge polarization voltage according to SOC of the battery cell 20 and the discharge polarization coefficient related to the increase in the voltage according to SOC among the polarization voltages (discharge polarization voltages) caused by the discharge of the battery cell 20. The measured values of the current and the voltage are obtained as the detected values of the current sensor 21 and the voltage sensor 22, for example. The estimation model is constructed, for example, on the basis of the closed-circuit-voltage (CCV: Closed Circuit Voltage) of the battery cell 20 as described below.

The charge notification unit 13 is an example of a notification unit. When SOC of the battery cell 20 is equal to or less than the threshold value, the charge notification unit 13 notifies the user of the vehicle V that the battery cell 20 is to be charged. The charge notification unit 13 acquires SOC and the discharge polarization coefficient calculated by the state calculation unit 12 through the operation control unit 10, and acquires the thresholds corresponding to the discharge polarization coefficients from the threshold map 141. Since the charge notification unit 13 determines whether charging is necessary using a threshold value corresponding to the discharge polarization coefficient, it is possible to appropriately prompt the user to charge the battery cell 20 according to the use state, as will be described later.

When SOC is less than or equal to the threshold, the charge notification unit 13 causes the in-vehicle display 3 to display a charge notification using, for example, a character or a symbol. Accordingly, the user recognizes that the battery cell 20 needs to be charged at an appropriate timing, and can perform charging at an appropriate timing before the power of the battery cell 20 is not in an excessive state and the power is insufficient. Note that, although the in-vehicle display 3 is described as a means for notifying the user of the charge in the present embodiment, the present disclosure is not limited to this, and other means such as sound notification by a speaker or light emission by LED (Light Emitting Diode) may be used.

### Processing of State Calculation Unit

$$CCV = OCV - IR - {V}_{C} - p \cdot a \{ \frac{( SOC - \frac{I \cdot Δ t \cdot 100}{3600 \cdot Cap} ) \cdot b - c}{d} \} \qquad ( 2 )$$

The state calculation unit 12 uses, for example, the above Equation (2) as an estimation model. In Equation (2), OCV is the open-circuit voltage of the battery cell 20, and SOC is the charge rate of the battery cell 20. I is a detection value of the current sensor 21, and R is an internal resistance value of the battery cell 20. Cap is the full charge capacity of the battery cell 20 (see Equation (1) above). At is an execution cycle of the calculation according to Equation (2).

Vc is a voltage (charge/discharge polarization voltage) that does not depend on SOC among the polarization voltages (charge polarization voltage and discharge polarization voltage) generated by the charge/discharge of the battery cell 20, and p is a discharge polarization coefficient. The values a to d are constants that are set in advance based on pre-experimental results or simulations.

In Equation (2), the term including the discharge polarization coefficient p, the constants a to d, the detected value I, the full charge capacity Cap, and the execution period Δt (discharge polarization estimation term) is a voltage that depends on the variation of SOC in the execution period Δt among the discharge polarization voltages of the battery cells 20. The discharge polarization estimation term estimates an increase in the discharge polarization voltage associated with an increase in the diffusion resistance in the low SOC range from a value obtained by multiplying the change amount of SOC in the execution period Δt by the discharge polarization coefficient p, which is a weighting coefficient, calculated from the ratio of the integrated value of the detected value I of the current to the full charge capacity Cap. The constants a to d are determined, for example, from the characteristics of the diffusion resistance at the time of discharge of the battery cell 20 described below.

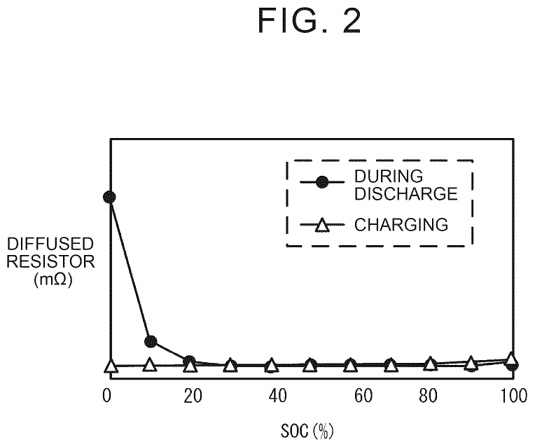

FIG. 2 is a diagram illustrating an exemplary change in diffusion resistance (mΩ) of a lithium-ion battery during charge (see “Δ”) and discharge (see “⋅”) with respect to SOC (%); The diffusivity during charge is substantially constant regardless of SOC. On the other hand, when SOC is 20 to 100%, the diffusivity is substantially constant, but when SOC is 0 to 20%, the diffusivity is increased as SOC is decreased.

As the diffusion resistance increases, the polarization voltage of the battery cell 20 increases. The discharge polarization coefficient p is a parameter indicating the degree (weight) of the increase in the discharge polarization voltage depending on SOC, and indicates a value larger than the other range in a range in which SOC is lower (0% to 20% in the above-described example). The state calculation unit 12 can calculate the state-of-charge with high accuracy by using the estimation model including the discharge polarization coefficient p, taking into account an increase in the discharge polarization voltage in a range where SOC is low. Note that the discharge polarization coefficient p is an example of a coefficient.

The state calculation unit 12 acquires the detected values I, V from the current sensor 21 and the voltage sensor 22 for each run cycle Δt, and calculates CCV by Equation (2). At this time, the state calculation unit 12 acquires the latest full charge capacity Cap from the capacity estimation unit 11. The state calculation unit 12 updates the internal resistance value R, the charge/discharge polarization voltage Vc, and the discharge polarization coefficient p for each of the execution cycles Δt in accordance with the difference between the detected value V and CCV of the voltage sensor 22. The state calculation unit 12 calculates SOC and the discharging polarization coefficient p so that the difference between CCV and the detected value V of the voltage sensor is minimized, for example, in accordance with the predictive error method.

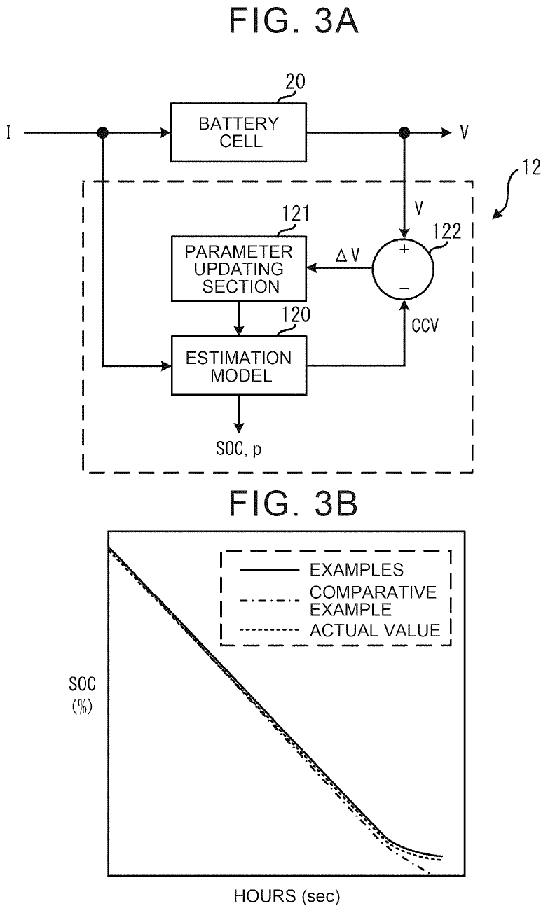

FIG. 3A is a functional block diagram illustrating an example of the state calculation unit 12. The state calculation unit 12 includes an estimation model 120 represented by Equation (2), a parameter updating unit 121, and an adder 122. The estimation model 120 calculates a CCV from Equation (2) in accordance with the detected value I of the current sensor 21 for each run cycle Δt, and outputs the calculated CCV to the adder 122.

The adder 122 receives the detected value V of the voltage sensor 22 and CCV calculated by the estimation model 120. The detected value V of the voltage sensor 22 is a closed circuit voltage corresponding to a current value flowing through the battery cell 20 (the detection value I of the current sensor 21). The adder 122 outputs the difference ΔV (=V−CCV) between the detected value V and CCV to the parameter updating unit 121.

$$SOC [ t + Δ t ] = SOC [ t ] - I \times Δ t / 3600 / Cap \times 100 + Ga \times Δ V \qquad ( 3 )$$

$$R [ t + Δ t ] = R [ t ] Gb \times Δ V \qquad ( 4 )$$

$$Vc [ t + Δ t ] = Vc [ t ] + Gc \times Δ V \qquad ( 5 )$$

$$p [ t + Δ t ] = p [ t ] + Gd \times Δ V \qquad ( 6 )$$

The parameter updating unit 121 updates SOC, the internal resistance value R, the charge/discharge polarization voltage Vc, and the discharge polarization coefficient p of the battery cell 20 according to the above Equations (3) to (6) in accordance with the difference ΔV between the detected value V and CCV. SOC, the internal resistance value R, the charge/discharge polarization voltage Vc, and the discharge polarization coefficient p are held in the memory 14 each time the calculation is performed.

In Equations (3) to (6), Ga, Gb, Gc, and Gd are the gains of the difference ΔV with respect to SOC, the internal resistance value R, the charge/discharge polarization voltage Vc, and the discharge polarization coefficient p, respectively. The gains Ga to Gd are set so that the difference ΔV converges on the basis of a previous experimental result, a simulated result, or the like. The internal resistance value R may be calculated by referring to the map data from the detected value and SOC of the temperature sensor 23 instead of Equation (4). At the beginning of the calculation, the parameter updating unit 121 calculates SOC [t+Δt] from the last held SOC [t] by using Equation (3) as the difference ΔV=0. The most recent values of SOC, the internal resistance value R, the charge/discharge polarization voltage Vc, and the discharge polarization coefficient p are stored in the memory 14 at any time, and the respective initial values are set based on the measured values of the battery cells 20.

The parameter updating unit 121 adds the product of the difference ΔV and each of the gains Ga to Gd to each of the values (see [t]) of SOC, the internal resistance value R, the charge/discharge polarization voltage Vc, and the discharge polarization coefficient p at the time t. Thus, the parameter updating unit 121 calculates each value ([t+Δt]) at the time (t+Δt). The parameter updating unit 121 outputs SOC of the time (t+Δt), the internal resistance value R, the charge/discharge polarization voltage Vc, and the discharge polarization coefficient p to the estimation model 120.

The estimation model 120 calculates a CCV from the internal resistance value R, the charge/discharge polarization voltage Vc, the discharge polarization coefficient p, and the detected value I of the current sensor 21, which are inputted from the parameter updating unit 121. At this time, the state calculation unit 12 calculates an OCV corresponding to SOC based on OCV map 140. The estimation model 120 outputs the discharging polarization coefficient p and SOC to the charge notification unit 13 via the operation control unit 10.

As described above, the state calculation unit 12 periodically calculates CCV of the battery cell 20 using the estimation model 120, and calculates SOC and the discharging polarization coefficient p in accordance with the prediction error method so that the difference ΔV between the calculated value of CCV and the detected value V of the voltage sensor 22 converges. Therefore, the state calculation unit 12 can calculate SOC and the discharge polarization coefficient p with high accuracy. Note that the state calculation unit 12 may calculate SOC and the discharging polarization coefficient p according to a method other than the predictive error method.

FIG. 3B is a diagram illustrating an exemplary temporal change in SOC (%) of the battery cell 20 during discharging. The solid line represents SOC calculated by the estimation model 120 using the above Equation (2) (Example), the dashed-dotted line represents SOC calculated by the estimation model 120 using the equation excluding the discharge-polarization estimation term from Equation (2) (Comparative Example), and the dotted line represents the actual measurement of SOC.

In the comparative example, since the increase in the discharge polarization voltage due to the increase in the diffusion resistance in the low SOC area as shown in FIG. 2 is not calculated, the error from the measured value is increased at a time when SOC is about 15% or less. On the other hand, in the embodiment, since the increment of the discharge polarization voltage is calculated by the discharge polarization estimation term, the error from the measured value is smaller than that in the comparative example even when SOC is about 15% or less.

As described above, the state calculation unit 12 can calculate SOC with high accuracy by reflecting the increase in the diffusion resistance at the time of discharge by the discharge polarization estimation term including the discharge polarization coefficient p.

### Processing of Charge Notification Unit

$$OCV - CCV - IR = {V}_{C} + p \cdot a \{ \frac{( SOC - \frac{I \cdot Δ t \cdot 100}{3600 \cdot Cap} ) \cdot b - c}{d} \} \qquad ( 7 )$$

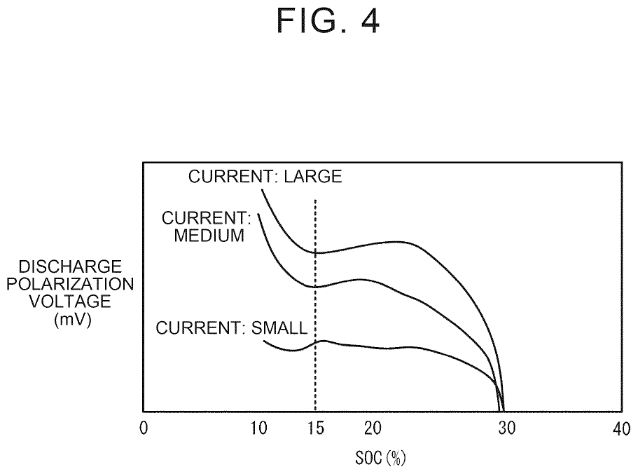

FIG. 4 is a diagram illustrating an exemplary change in discharge-polarization voltage (mV) with respect to SOC (%); This example shows a simulated result obtained by calculating the discharge polarization voltage when the battery cell 20 having a SOC of 30% is discharged while the current is maintained constant, using the left side of the above-described Equation (7) obtained from the Equation (2). Here, the magnitude of the current (I in Equation (7)) is three of “large”, “medium”, and “small”.

The discharge polarization voltage increases as the current of the battery cell 20 increases. In the regions where SOC is less than about 15%, the discharge-polarization voltage increases with decreasing SOC due to the increase in the diffusion-resistance. At this time, the degree of increase in the discharge polarization voltage is larger as the current of the battery cell 20 is larger. For this reason, in an area where SOC is about 15% or less, the electric power of the battery cell 20 is consumed in accordance with an increase in the voltage corresponding to SOC.

Therefore, when SOC is low, there is a variation in the effect of the discharging polarization depending on the use condition of the battery cell 20. If the charge notification unit 13 prompts the user to charge the battery cell 20 when SOC is 15% or less at all times regardless of the magnitude of the current, and if the current is “small”, it is considered that there is an excessive margin in the power of the battery cell 20. For example, when the vehicle V is traveling on a general road, since the current of the battery cell 20 is small (current “small”), the notification of charging is fast, and it is difficult to consume electric power without waste.

On the other hand, when the current is “large” or “medium”, it is considered that the power of the battery cell 20 is excessively insufficient. For example, when the vehicle V is traveling on the expressway, the current of the battery cell 20 is large (current “large”), so that the notification of charging is slow, and there is a possibility that the vehicle V may be hindered from traveling due to insufficient power.

Therefore, the charge notification unit 13 decreases the threshold value (SOC threshold value) of SOC used for notification of charge as the discharge polarization coefficient p decreases. For example, the charge notification unit 13 acquires a threshold value corresponding to the discharge polarization coefficient p from the threshold map 141.

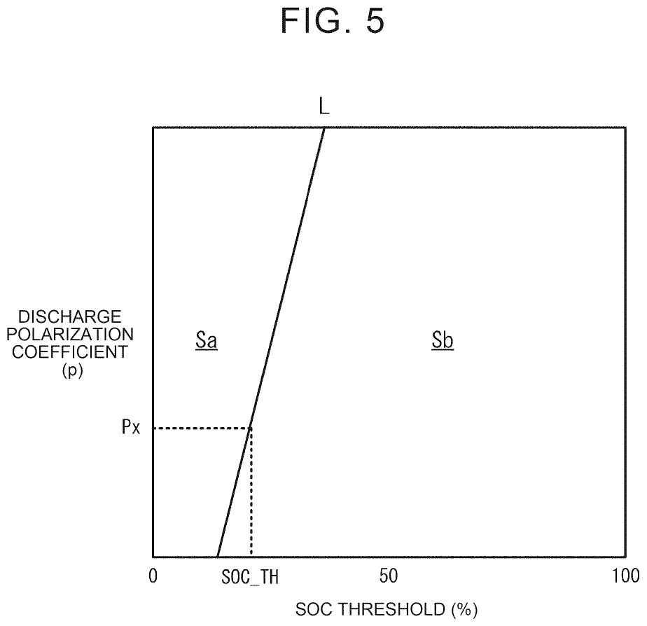

FIG. 5 is a diagram illustrating an example of the threshold map 141. In FIG. 5, the horizontal axis represents SOC threshold (%), and the vertical axis represents discharging polarization coefficient p. Line L shows the relation between the discharge-polarization coefficient p and SOC thresholds. In the present embodiment, the discharge-polarization coefficient p and SOC thresholds have a linear relation. The charge notification unit 13 acquires SOC thresholds corresponding to the discharging polarization coefficient p based on the line segment L. For example, when the discharging polarization coefficient p is Px, the SOC_TH is SOC threshold based on the line segment L.

Charge notification unit 13, if SOC is equal to or less than SOC threshold value, and displays a notification prompting the charging of the battery cell 20 to the user on the in-vehicle display 3, if SOC is greater than SOC threshold value, the notification is not displayed on the vehicle-mounted display 3. That is, the charge notification unit 13 does not perform notification when SOC and the discharge polarization coefficient p calculated by the state calculation unit 12 are located on the side where the region Sb (larger SOC threshold) among the two areas Sa, Sb separated by the line segment L. On the other hand, the charge notification unit 13 executes the notification when SOC and the discharge polarizing coefficient p are located at the area Sa (smaller SOC threshold) among the two areas Sa, Sb separated by the line segment L.

As described above, the charge notification unit 13 determines whether the charge notification is possible by using the larger SOC thresholds as the discharging polarization coefficient p is larger. Therefore, in the case of the example of FIG. 4, when the current is “large” or “medium”, the possibility of the charge notification is determined based on SOC thresholds larger than the case where the current is “small”. Therefore, the control device 1 can prompt the user to charge the battery cell 20 at an appropriate timing according to the use state of the battery cell.

In addition, the charge notification unit 13 changes SOC thresholds so that a linear relation is established with the discharging polarization coefficient p. Therefore, when the diffusivity of the battery cell 20 during discharging increases linearly with the decrease in SOC, SOC thresholds can be set with high accuracy. The maximal value and the minimal value of SOC thresholds are appropriately set in accordance with the usage conditions of the battery cells 20.

### Operation of Control Device

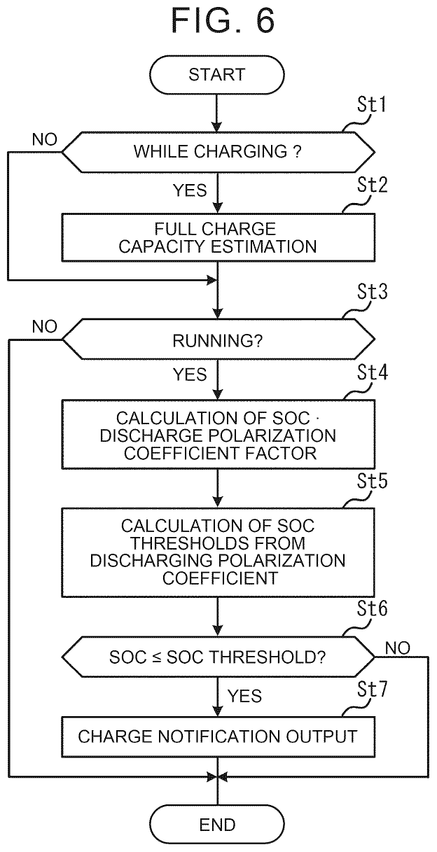

FIG. 6 is a flowchart illustrating an example of the operation of the control device 1. This operation is executed, for example, at regular time intervals.

First, the operation control unit 10 determines whether the battery cell 20 is being charged (St1). When the battery cell 20 is being charged (Yes of St1), the capacity estimation unit 11 estimates the full charge capacity Cap of the battery cell 20 (St2). When the battery cell 20 is not being charged (No of St1), St2 operation is not performed.

Next, the operation control unit 10 determines whether the vehicle V is traveling (St3). When the vehicle V is not traveling (No of St3), the operation ends. When the vehicle V is traveling (Yes of St3), the state calculation unit 12 calculates SOC and the discharge polarization coefficient p of the battery cell 20 during discharging by the above-described method (St4). During traveling of the vehicle V, electric power is supplied from the battery cell 20 to the electric motor 5.

Next, the charge notification unit 13 calculates SOC threshold based on the threshold map 141 from the discharged polarization coefficient p (St5). Next, the charge notification unit 13 compares SOC with SOC thresholds (St6). When SOC≤SOC threshold is satisfied (Yes of St6), the charge notification unit 13 outputs a charge notification to the in-vehicle display 3 (St7). When SOC>SOC threshold is satisfied (No of St6), the charge notification unit 13 ends the operation without outputting the charge notification. In this way, the control device 1 operates.

As described above, the state calculation unit 12 calculates SOC and the discharge polarization coefficient p from the detected values I, V of the current and the voltage of the battery cell 20 based on the estimation model 120 that estimates the discharge polarization voltage according to SOC of the battery cell 20 and the discharge polarization coefficient p relating to the increase in the voltage according to SOC among the discharge polarization voltages of the battery cell 20. When SOC is equal to or less than SOC threshold, the charge notification unit 13 notifies the user of charge of the battery cell 20, and decreases SOC threshold as the discharge polarization coefficient p decreases.

Therefore, the state calculation unit 12 can calculate SOC and the discharge polarization coefficient p with high accuracy by reflecting the increase in the discharge polarization voltage accompanying the increase in the diffusion resistance in the low SOC area during the discharge of the battery cell 20. In addition, the charge notification unit 13 reduces SOC thresholds as the discharge polarization coefficient p decreases, so that the user can appropriately prompt the user to charge the battery in accordance with the increase in the discharge polarization voltage.

In addition, when a lithium-ion battery is used as the battery cell 20, it is preferable because it has high versatility. In addition, since the battery cell 20 supplies electric power to the electric motor 5 that drives the vehicle V, it is possible to appropriately urge the user to charge the battery by the operation of the control device 1 described above while the vehicle V is traveling. Note that the control device 1 is not limited to the vehicle V, and may be used, for example, to notify charging of a battery cell of an electronic device such as a smartphone.

The embodiments described above are examples of preferred embodiments of the present disclosure. However, the present disclosure is not limited to this, and various modifications can be made without departing from the gist of the present disclosure.

What is claimed is:

1. A battery management device, comprising:
a calculation unit that, based on an estimation model that estimates a polarization voltage in accordance with a State Of Charge (SOC) of a battery and a coefficient relating to increase in voltage corresponding to the SOC out of polarization voltage due to discharging of the battery, calculates the SOC and the coefficient from measured values of current and voltage of the battery; and
a notification unit that, when the SOC is no greater than a threshold value, gives a notification to prompt a user to charge the battery, wherein
the smaller the coefficient is, the lower the notification unit sets the threshold value.

2. The battery management device according to claim 1, wherein the notification unit changes the threshold value such that a linear relationship is established with the coefficient.

3. The battery management device according to claim 1, wherein the calculation unit periodically calculates the voltage of the battery using the estimation model, and calculates the SOC and the coefficient such that a difference between a calculated value of the voltage of the battery and the measured value of the voltage of the battery converges.

4. The battery management device according to claim 1, wherein the battery is a lithium-ion battery.

5. The battery management device according to claim 1, wherein the battery supplies electric power to an electric motor that drives a vehicle.
